(19) United States
(12) Patent Application Publication
(10) Pub. No.: US 2014/0103455 A1
(43) Pub. Date: Apr. 17, 2014

(54) FET Devices with Oxide Spacers

(71) Applicant: INTERNATIONAL BUSINESS MACHINES CORPORATION, Armonk, NY (US)

(72) Inventors: Takashi Ando, Tuckahoe, NY (US); Pranita Kerber, Mount Kisco, NY (US); Tenko Yamashita, Schenectady, NY (US)

(73) Assignee: INTERNATIONAL BUSINESS MACHINES CORPORATION, Armonk, NY (US)

(21) Appl. No.: 13/653,699

(22) Filed: Oct. 17, 2012

(51) Int. Cl. H01L 29/78; H01L 21/336

(52) U.S. Cl. 257/410; 438/300; 257/E21.409; 257/E29.255

(57) ABSTRACT

Transistors including oxide spacers and methods of forming the same. Embodiments include planar FETs including a gate on a semiconductor substrate, oxide spacers on the gate sidewalls, and source or drain regions at least partially in the substrate offset from the gate by the oxide spacers. Other embodiments include finFETs including a fin on an insulator layer, a gate formed over the fin, a first source or drain region on a first end of the fin, a second source or drain region on a second end of the fin, and oxide spacers on the gate sidewalls separating the first source or drain region and the second source or drain from the gate. Embodiments further include methods of forming transistors with oxide spacers including forming a transistor including sacrificial spacers, removing the sacrificial spacers to form recess regions, and forming oxide spacers in the recess regions.

### FIELD OF THE INVENTION

The present invention generally relates to semiconductor devices, and particularly to FET devices with oxide spacers and methods for making the same.

### BACKGROUND

Metal-oxide-semiconductor (MOS) technology is a commonly used technology for fabricating field effect transistors (FETs) as part of advanced integrated circuits, such as CPUs, memory, and storage devices, and the like. In MOS technology, a FET may be formed by depositing a gate structure over a channel region connecting a source and a drain. For planar FETs, the channel region is formed in a semiconductor substrate on which the gate structure is formed. In finFETs, the gate structure may be formed over or around a semiconductor fin on an insulator layer, with a source and a drain formed on opposite ends of the semiconductor fin.

In MOS technology, the gate structure may be made of a gate dielectric and a gate electrode. In traditional MOS-FETs, the gate dielectric consists of a silicon dioxide layer intended in part to prevent current from leaking from the gate electrode into the channel. However, as the critical dimensions of modern microelectronic structures continues to decrease, silicon dioxide gate dielectrics may not be reliably used as gate dielectrics. Therefore, an increasing trend in microelectronic device is to at least partially replace the silicon dioxide gate dielectric with a high-k dielectric, such as tantalum nitride, strontium titanium oxide, hafnium oxide, hafnium silicon oxide, aluminum oxide or zirconium oxide. These high-k dielectrics may be reliably fabricated with thicknesses much greater than an equivalent silicon dioxide layer while maintaining approximately the same ability to prevent leakage. However, high-k dielectrics result in FETs with much higher threshold voltages (i.e., the voltage required to allow carriers to flow through the channel from the source to the drain). Therefore, it would be advantageous to develop a method for forming FETs having high-k gate dielectrics that, among other things, have improved threshold voltage performance.

### SUMMARY

The present invention relates to transistor structures having oxide gate spacers and methods for forming said transistor structures. According to one exemplary embodiment, transistor structures may be formed including sacrificial spacers made of, for example, silicon nitride. The sacrificial spacers may then be removed using, for example, a wet chemical etch including at least one of phosphoric acid and hydrofluoric acid to form spacer recess regions. Oxide spacers may then be formed in the spacer recess regions to provide a source oxygen to the transistor structure. The oxide spacers may be formed by depositing trisilylamine in the spacer recess regions via chemical vapor deposition with an oxygen and ammonia mixture; and steam-annealing the transistor structure.

Other embodiments may include planar field effect transistors including a gate on a semiconductor substrate. The gate may further include a high-k gate dielectric layer on the substrate, for example hafnium oxide, and a gate electrode on the high-k gate dielectric layer. Embodiments may further include oxide spacers on sidewalls of the gate and source or drain regions at least partially in the substrate. The source or drain regions may be laterally offset from the gate by the oxide spacers and may include raised source or drains. In some embodiments, the oxide spacers may be made of silicon oxide and cover a top portion of the source or drain regions.

Other embodiments include finFET structures including a semiconductor fin, a gate formed over a center portion of the semiconductor fin, a first source or drain region on one end of the semiconductor fin, a second source or drain region on the other end of the semiconductor fin, and oxide spacers on sidewalls of the gate separating the first source or drain region and the second/source drain region from the gate. In some embodiments, the oxide spacers may be made of silicon oxide and cover a top portion of the source or drain regions.

### BRIEF DESCRIPTION OF THE DRAWINGS

FIGS. 1A-8D depict steps of a method of fabricating a finFET having oxide gate spacers, according to an embodiment of the invention.

FIGS. 1A-1D depict a SOI substrate from which a finFET having oxide gate spacers may be fabricated, according to an embodiment of the invention.

FIGS. 2A-2D depict forming a plurality of fins from a semiconductor layer of the SOI substrate of FIGS. 1A-1D, according to an embodiment of the invention.

FIGS. 3A-3D depict forming a gate structure over the plurality of fins formed in FIGS. 2A-2D, according to an embodiment of the invention.

FIGS. 4A-4D depict forming sacrificial spacers on the sidewalls of the gate structure formed in FIGS. 3A-3D, according to an embodiment of the invention.

FIGS. 5A-5D depict forming source or drain regions on the ends of the fins adjacent to the sacrificial spacers formed in FIGS. 4A-4D, according to an embodiment of the invention.

FIGS. 6A-6D depict forming silicide layers on a top surface of the source or drain regions and a top surface of the gate structure, according to an embodiment of the invention.

FIGS. 7A-7D depict removing the sacrificial spacers to form spacer recess regions, according to an embodiment of the invention.

FIGS. 8A-8D depict filling the spacer recess regions with a flowable oxide to form oxide spacers, according to an embodiment of the invention.

FIGS. 9-16 depict steps of a method of fabricating a planar FET having oxide gate spacers, according to an embodiment of the invention.

FIG. 9 depicts a gate stack formed on a semiconductor substrate, according to an embodiment of the invention.

FIG. 10 depicts forming a gate structure from the gate stack of FIG. 9, according to an embodiment of the invention.

FIG. 11 depicts forming sacrificial spacers on the gate structure of FIG. 10, according to an embodiment of the invention.

FIG. 12 depicts forming source or drain recess regions in regions of the semiconductor substrate horizontally adjacent to the sacrificial spacers formed in FIG. 11, according to an embodiment of the invention.

FIG. 13 depicts forming source or drain regions in the source or drain recess regions formed in FIG. 12, according to an embodiment of the invention.

FIG. 14 depicts forming silicide layers on a top surface of the source or drain regions and a top surface of the gate structure, according to an embodiment of the invention.

FIG. 15 depicts removing the sacrificial spacers to form spacer recess regions, according to an embodiment of the invention.

FIG. 16 depicts filling the spacer recess regions with a flowable oxide to form oxide spacers, according to an embodiment of the invention.

Elements of the figures are not necessarily to scale and are not intended to portray specific parameters of the invention. For clarity and ease of illustration, scale of elements may be exaggerated. The detailed description should be consulted for accurate dimensions. The drawings are intended to depict only typical embodiments of the invention, and therefore should not be considered as limiting the scope of the invention. In the drawings, like numbering represents like elements.

### DETAILED DESCRIPTION

Exemplary embodiments now will be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

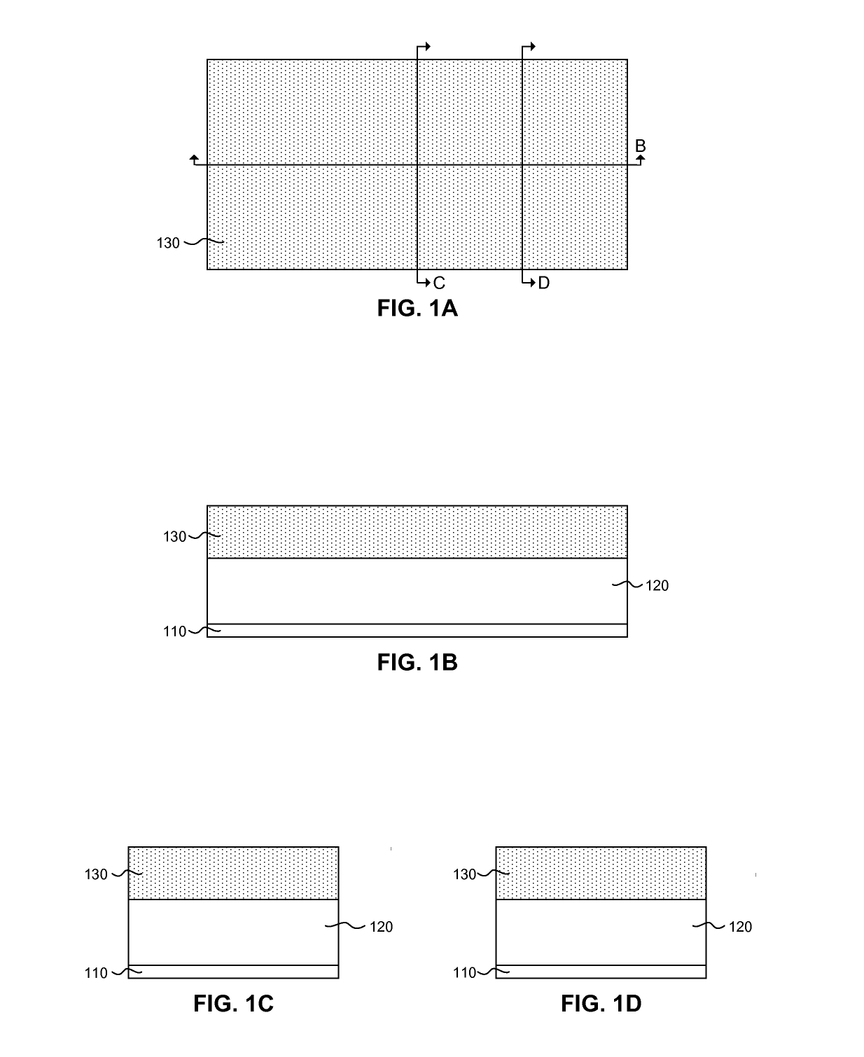

Referring to FIGS. 1A-1D, a stack of layers is depicted from which an exemplary embodiment may be constructed. As applicable to FIGS. 1A-1D, 2A-2D, 3A-3D, 4A-4D, 5A-5D, 6A-6D, 7A-7D, and 8A-8D, figures with the suffix “B”, “C”, or “D”, are vertical cross-sectional views of the exemplary structure along the plane indicated by line B, C, or D, respectively, of the corresponding figure with the same numeric label and the suffix “A.” As seen in the cross-sectional views depicted in FIGS. 1B-1D, the stack of layers may include a base substrate 110, a buried oxide (BOX) layer 120, and a semiconductor-on-insulator (SOI) layer 130. While the depicted embodiment includes the BOX layer 120 and SOI layer 130, other embodiments may exclude the layers and form transistor structures directly on base substrate 110. Base substrate 110 may be made of any semiconductor material including, but not limited to: silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. BOX layer 120 may be formed from any of several dielectric materials. Non-limiting examples include, for example, oxides, nitrides, and oxynitrides of silicon, and combinations thereof. Oxides, nitrides and oxynitrides of other elements are also envisioned. Further, BOX layer 120 may include crystalline or non-crystalline dielectric material. Box layer 120 may be approximately 50 to approximately 500 nm thick, preferably approximately 200 nm. SOI layer 130 may be made of any of the several semiconductor materials possible for base substrate 110. In general, base substrate 110 and SOI layer 130 may include either identical or different semiconducting materials with respect to chemical composition, dopant concentration and crystallographic orientation. SOI layer 130 may be p-doped or n-doped with a dopant concentration of approximately 1×10¹⁵ to approximately 1×10¹⁸/cm³, preferably approximately 1×10¹⁵/cm³. SOI layer 130 may be approximately 50 to approximately 300 nm thick, preferably approximately 100 nm.

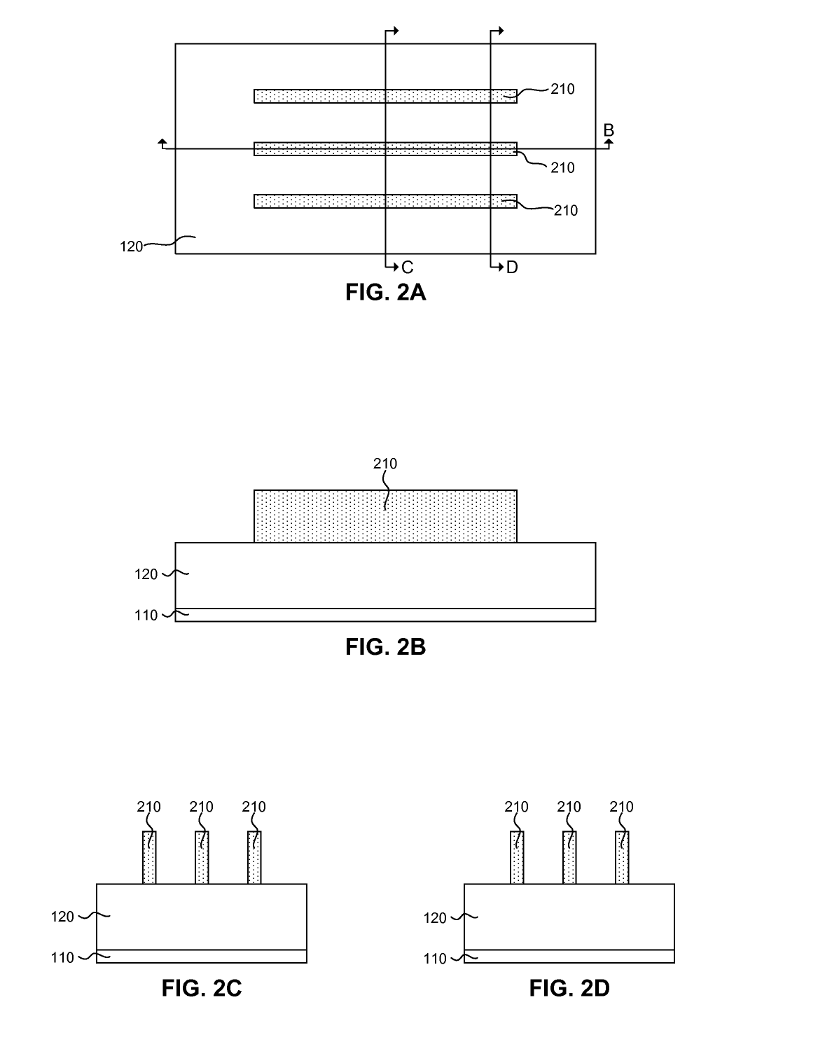

Referring to FIGS. 2A-2D, at least one semiconductor fin 210 may be formed by removing excess material from SOI layer 130 (FIGS. 1A-1D) using any method known in the art including, for example, a photolithography process followed by etching process, such as reactive ion etching (RIE). It should be noted that a single finFET device may have one or more fins. In the depicted embodiment, three fins 210 are formed. Other embodiments may include more than three, or as few as one, fin. Fins 210 may have a width of approximately 8 nm to approximately 30 nm, preferably approximately 10 nm.

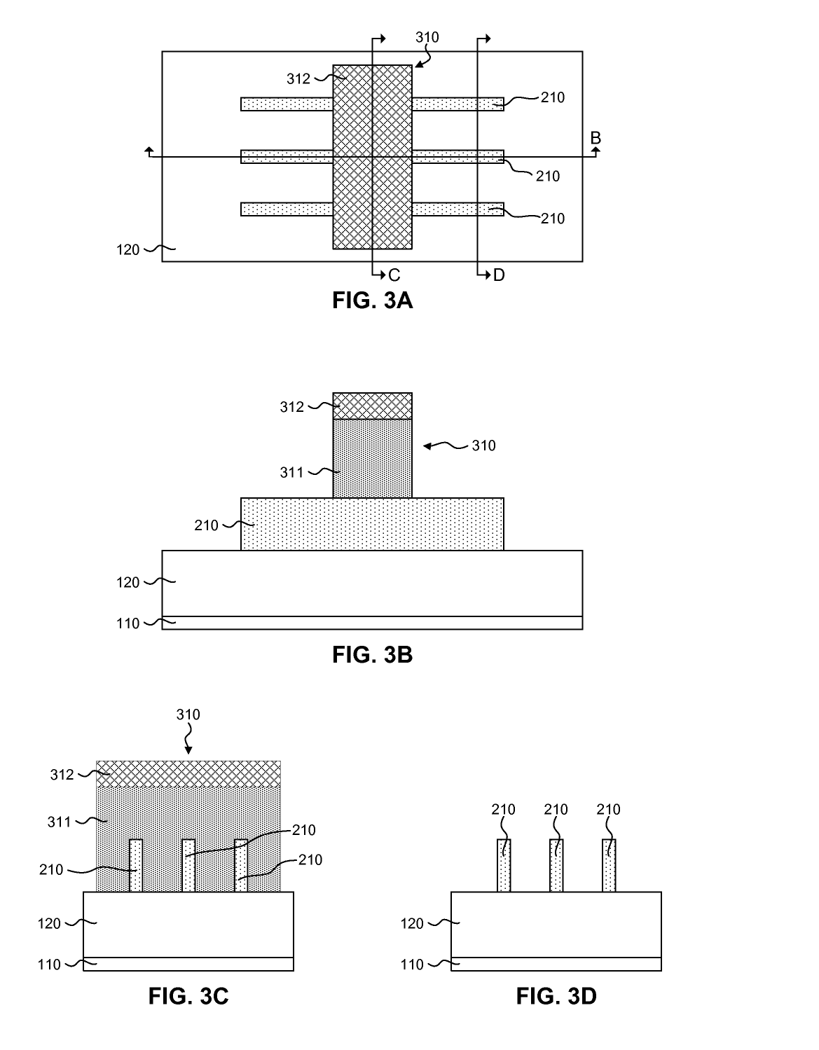

Referring to FIGS. 3A-3D, a gate 310 may be formed over a central portion of fins 210. Gate 310 may include gate electrode 311 and gate hard mask 312. Gate hard mask 312 may be made of, for example, a nitride material and may be approximately 20 nm to approximately 50 nm thick, preferably approximately 25 nm. In some embodiments, gate 310 may be formed using a gate-first process, in which case gate electrode 311 may further include a gate dielectric layer, work-function metal layers, and a metal fill layer. The gate dielectric layer may be made of metal oxides, metal silicates, metal nitrides, transition metal oxides, transition metal silicates, transition metal nitrides, or combinations thereof, and may be approximately 1 nm to approximately 5 nm thick. Exemplary gate dielectric layer materials include silicon dioxide, hafnium oxide, and aluminum oxide. The work-function metal layers may include multiple metal-containing layers and may be made of titanium nitride, tantalum nitride, or titanium-aluminum and may be approximately 20 to approximately 100 angstroms thick. The metal fill layer may be made of, for example, silicon, aluminum, copper, tungsten, or some combination thereof. Other embodiments may include more or less metal layers depending on the application and types of device being formed. The composition of each metal layer may also vary and the process of selecting the material for each metal layer is known in the art.

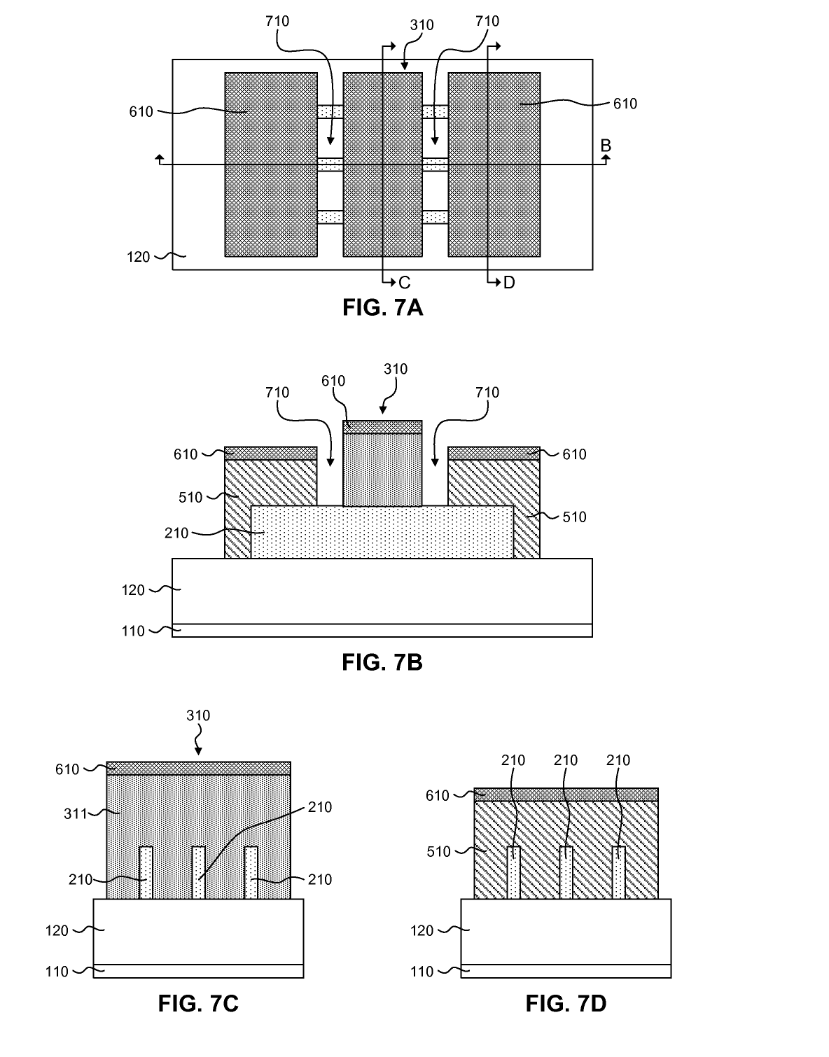

In some other embodiments, gate 310 may be formed using a gate-last process, in which case gate electrode 311 may include a sacrificial layer made of, for example, silicon intended to serve as a placeholder for the replacement gate formed after later processing steps. In embodiments where a gate-last process is used, gate electrode 311 may be removed and a replacement metal gate formed prior to the removal of the nitride spacers described below in conjunction with FIGS. 7A-7D.

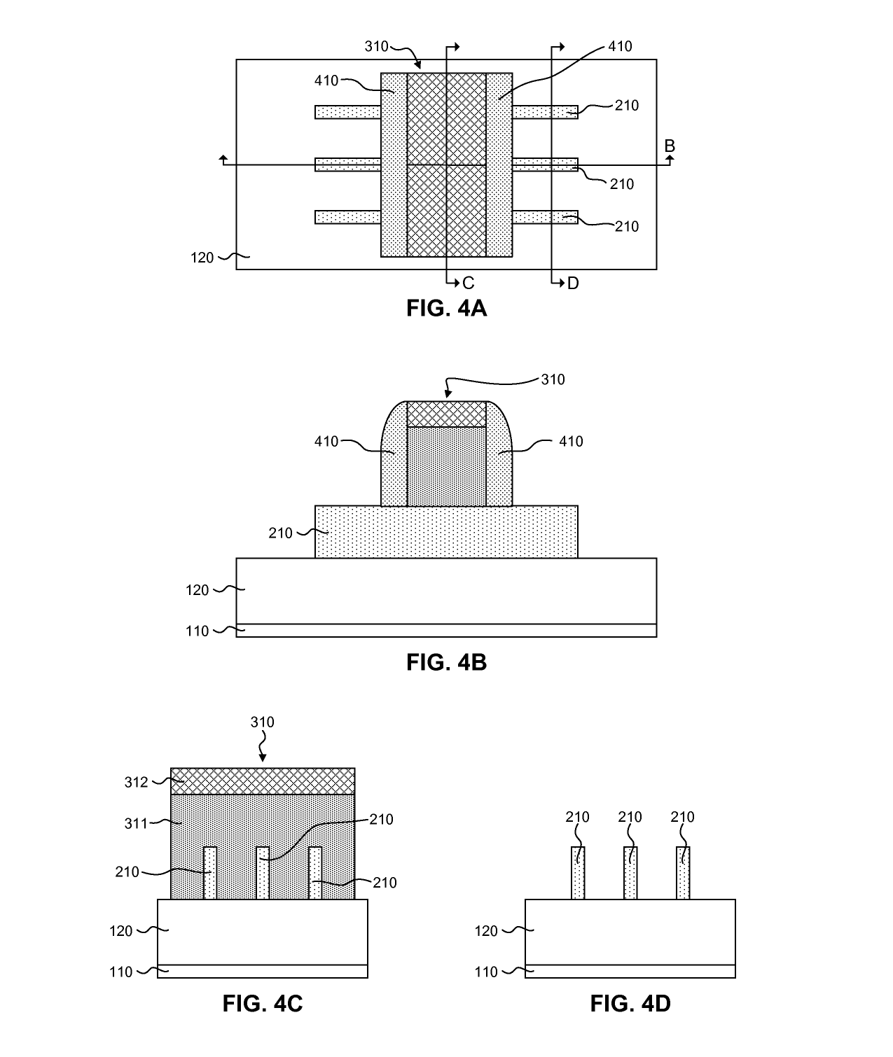

Referring to FIGS. 4A-4D, sacrificial spacers 410 may be formed on the sides of gate 310 at a perpendicular orientation relative to fins 210. Sacrificial spacers 410 may be formed, for example, by depositing a silicon nitride (e.g., SiN or Si₃N₄) layer over gate 310 and then removing excess material using an anisotropic reactive ion etching process, such as RIE (not shown). Due to the etching process, sacrificial spacers 410 may have a curved top surface on their edges opposite gate 310. In other embodiments, sacrificial spacers 410 may be made of tetraethyl orthosilicate (TEOS) deposited oxide, or plasma-enhanced chemical vapor deposited (PECVD) oxide, or Si_{w}OₓN_{y}, Si_{w}Cₓ, Si_{w}OₓC_{y}N_{z}. The thickness of sacrificial spacers 410 may be approximately 10 to approximately 15 nm and may fully cover the portions of fins 210 adjacent to gate 310.

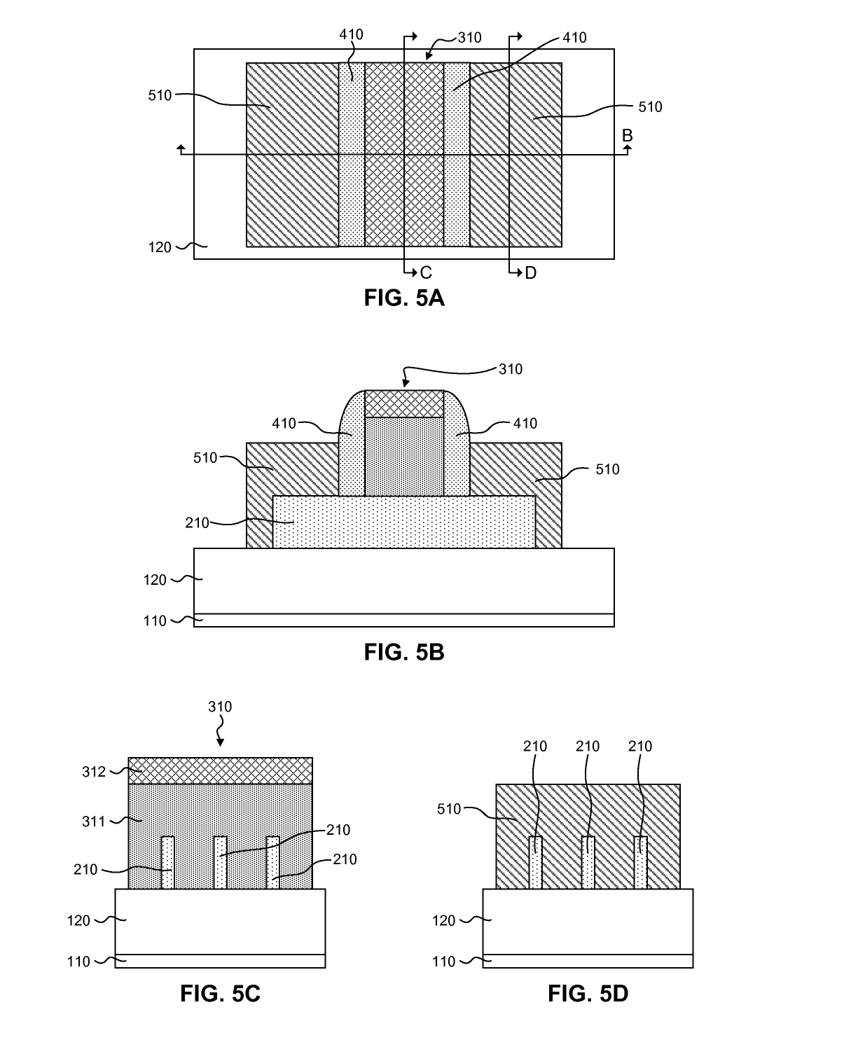

Referring to FIGS. 5A-5D, source or drain regions 510 may be formed over the portions of fins 210 (FIGS. 4A-4E) not covered by gate 310 or sacrificial spacers 410, using any known method in the art. In some embodiments, source or drain regions 510 may be formed by growing silicon-containing semiconductor material over the exposed portions of fins 210 using known epitaxial growth processes. In other embodiments, source or drain regions 510 may be formed by depositing silicon using, for example, chemical vapor deposition (CVD). For NMOS finFETs, source or drain regions 510 may be made of, for example, silicon or carbon-containing silicon (containing, for example, approximately 1-3% C) with a dopant concentration of approximately 1×10²⁰ to approximately 8×10²⁰/cm³ of arsenic or phosphorus, preferably approximately 5×10²⁰/cm³. For PMOS finFETs, source or drain regions 510 may be made of, for example, silicon or silicon germanium with a dopant concentration of approximately 5×10¹⁹ to approximately 5×10²⁰/cm³ of boron, preferably approximately 3×10²⁰/cm³. Source or drain regions 510 may be doped, for example, using either an in-situ doping process or an ion implantation process before or after forming source or drain regions 510. It should be noted that, while source or drain regions 510 are depicted as has having uniform geometries in the provided figures, some known epitaxial processes may result in non-ideal geometries where faceting may be present. In particular, faceting and/or voiding may occur where growths on opposing sidewalls of adjacent fins meet. Source or drain regions 510 may have a height of approximately approximately 20 to approximately 40 nm.

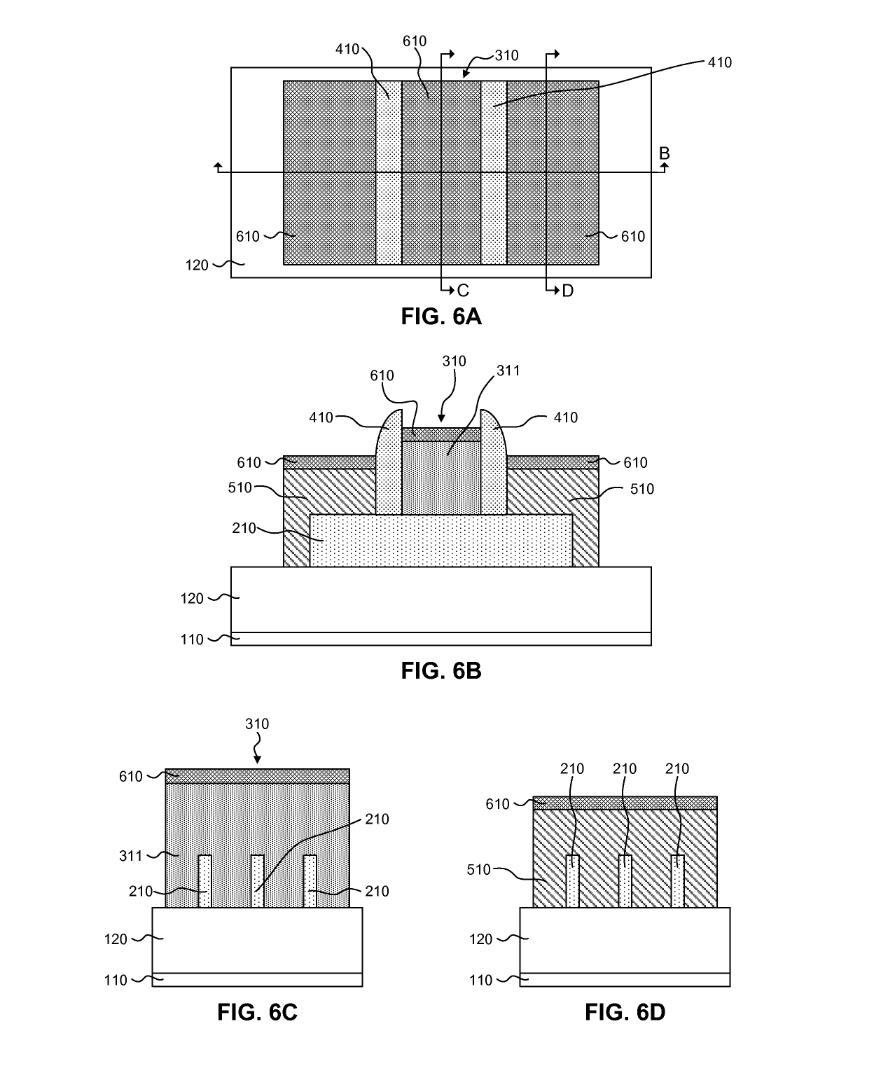

Referring to FIGS. 6A-6D, silicide layers 610 may be formed on a top surface of source or drain regions 510 and gate electrode 311 of gate 310. In embodiments where a gate last process is used (as described above in conjunction with FIGS. 3A-3D), the sacrificial layer of gate electrode 311 should be replaced prior to the silicide process. Silicide layers 610 may be formed by first depositing a uniform metal layer (not shown) over the top surface of the structure of FIGS. 5A-5D. The metal layer may be deposited by any thin film deposition technique available in the industry including, but not limited to, physical vapor deposition (i.e. sputter deposition) or chemical vapor deposition or evaporation. The metal layer may be made of materials including, for example, nickel, platinum, titanium, cobalt or some combination thereof, and may be approximately 3 nm to approximately 10 nm. The metal layer may then be annealed (not shown) so that the metal layer reacts with any underlying reactive surfaces (primarily silicon-containing materials) to form silicide layers 610. The annealing process may typically be performed by a rapid thermal annealing (RTA) process at peak temperatures ranging from approximately 300 to approximately 900 degrees Celsius, depending on the silicide material. After removal of any remaining unreacted metal material (not shown), silicide layers 610 may remain directly in contact with source or drain regions 510 and gate electrode 311, as shown in FIG. 6A-6D. In embodiments where gate electrode 311 is made of a metal such as copper, aluminum, or tungsten, silicide layer 610 may not be present on the top surface of gate electrode 311.

Referring to FIGS. 7A-7D, sacrificial spacers 410 may be removed to form spacer recess regions 710. Sacrificial spacers 410 may be selectively etched so that they are removed without causing substantial damage to any other element of the structure. Sacrificial spacers 410 may be removed by a suitable wet chemical etch process that selectively removes the spacer material. For example, silicon nitride spacer removal may be accomplished by the use of hot phosphoric acid, hydrofluoric acid, or a combination thereof.

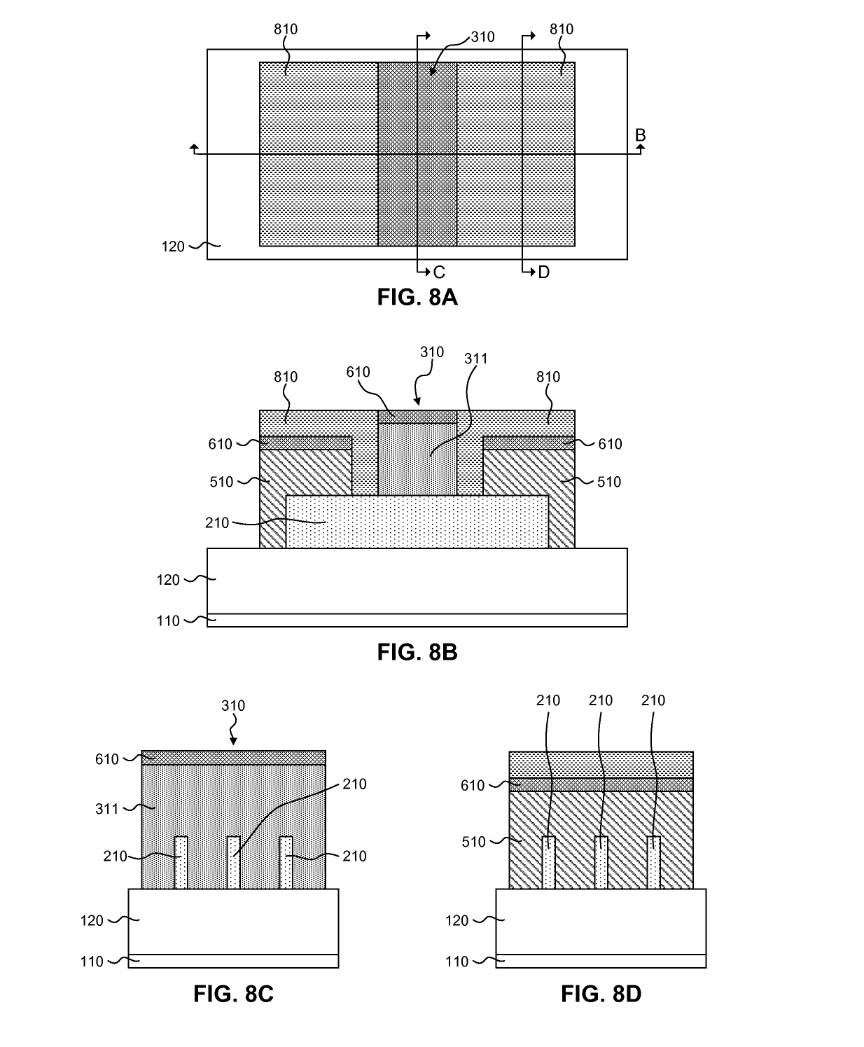

Referring to FIGS. 8A-8D, spacer recess regions 710 (FIGS. 7A-7D) are filled by oxide spacers 810. Oxide spacers 810 may be made of, for example, a flowable oxide material. Oxide spacers 810 may be formed by may be formed by first depositing a silicon precursor such as trisilylamine [TSA, (SiH₃)₃N] via chemical vapor deposition with an oxygen (O₂) and ammonia (NH₃) mixture. The TSA may be deposited at temperatures below approximately 50° C. to enhance formation of short-chain polymers on the surface of the structure resulting in a liquid-like flowable film capable of filling dense, high-aspect ratio re-entrant profiles, such as spacer recess regions 710. After the low temperature deposition of TSA, the wafer may be steam annealed between approximately 350 to approximately 550° C. for approximately 2 to approximately 4 hours to allow dehydrogenation and denitrogenation of TSA leading to formation of silicon oxide (SiO₂) capable of filling spacer recess regions 710 without leaving a substantial volume of voids. In some embodiments, oxide spacers 810 may extend beyond spacer recess regions 710, and, for example, cover the top surfaces of silicide layers 610 above source or drain regions 510, as depicted in FIGS. 8A-8D. In other embodiments, oxide spacers 810 may fully cover the top surface of the structure depicted in FIG. 7A, including covering the top surface of silicide layers 610 above gate electrode 311 (not shown). In some embodiments, some or all excess oxide may be removed by, for example, chemical-mechanical planarization (CMP). After formation of oxide spacers 810, the structure is ready for standard back-end-of-the-line processes, including deposition of interlevel dielectric layers and contact formation.

It is known that oxygen vacancies may be generated in the high-k dielectric layers of FETs, such as hafnium-based dielectrics, during CMOS integration, which subsequently results in higher threshold voltages. This particularly may occur for gate-first processes, which require high-temperature anneals after formation of high-k metal gate stacks for dopant activation that may exacerbate the formation of oxygen vacancies. However, gate-last process may still be negatively impacted, as oxygen vacancies may still be generated by back-end-of-line process that may take place at temperatures of approximately 400° C. to approximately 500° C. By replacing sacrificial spacers 410 with oxide spacers 810, an internal source of oxygen that may fill oxygen vacancies in the high-k dielectric layer of gate electrode 311 may be provided within the FET. In addition, parasitic capacitance of oxide spacers 810 may be lower compared with conventional nitride spacers, potentially resulting in faster devices with lower power consumption.

The spacer replacement process described above in conjunction with FIGS. 7A-7D and 8A-8D is also applicable to embodiments where a planar field effect transistor (planar FET) is formed, rather than a finFET. A similar method of manufacturing a transistor structure with oxide spacers, but with a planar FET rather than a finFET, is discussed below in conjunction with FIGS. 9-16.

Referring to FIG. 9, a stack of layers, including semiconductor substrate 910, gate stack 920, and hard mask layer 930, is depicted from which an exemplary embodiment may be constructed. Semiconductor substrate 910 may be made of any semiconductor material including, but not limited to: silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. Semiconductor substrate 910 may be p-doped or n-doped and include an oppositely-doped well, the details of which have been omitted for illustrative clarity. Semiconductor substrate 910 may be 5 nm to hundreds of microns thick. Hard mask layer 312 may be made of, for example, a nitride material and may be approximately 20 to approximately 50 nm thick, preferably approximately 25 nm.

In gate-first processes, gate stack 920 may further include a gate dielectric layer, work-function metal layers, and a metal fill layer. The gate dielectric layer may be made of metal oxides, metal silicates, metal nitrides, transition metal oxides, transition metal silicates, transition metal nitrides, or combinations thereof, and may be approximately 2 nm-10 um thick. Exemplary gate dielectric layer materials include silicon dioxide, hafnium oxide, and aluminum oxide. The work-function metal layers may include multiple metal-containing layers and may be made of titanium nitride, tantalum nitride, or titanium-aluminum and may be approximately 20 to approximately 70 angstroms thick. The metal fill layer may be made of, for example, silicon, aluminum, copper, tungsten, or some combination thereof. Other embodiments may include more or less metal layers depending on the application and types of device being formed. The composition of each metal layer may also vary and the process of selecting the material for each metal layer is known in the art.

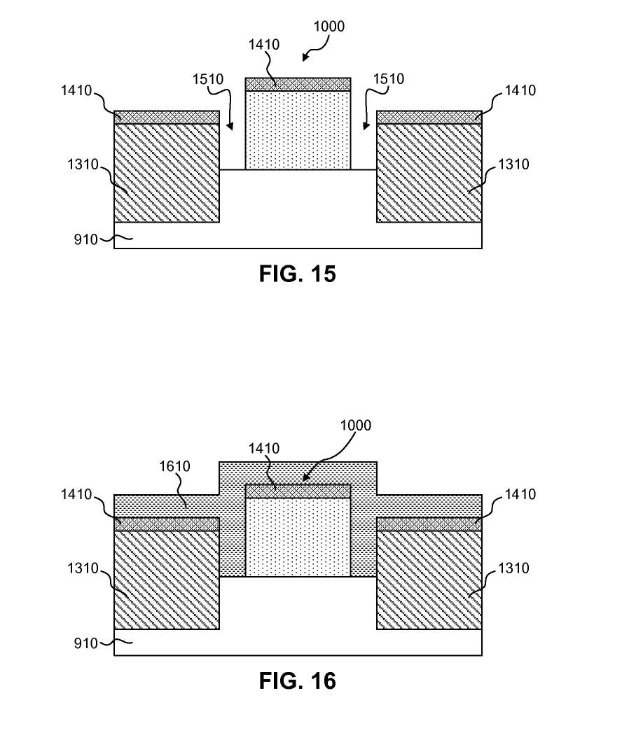

In gate-last processes, gate stack 920 may include a sacrificial layer made of, for example, silicon intended to serve as a placeholder for the replacement gate formed after later processing steps. In embodiments where a gate-last process is used, gate electrode 311 may be removed and a replacement gate formed prior to the removal of the nitride spacers described below in conjunction with FIG. 15.

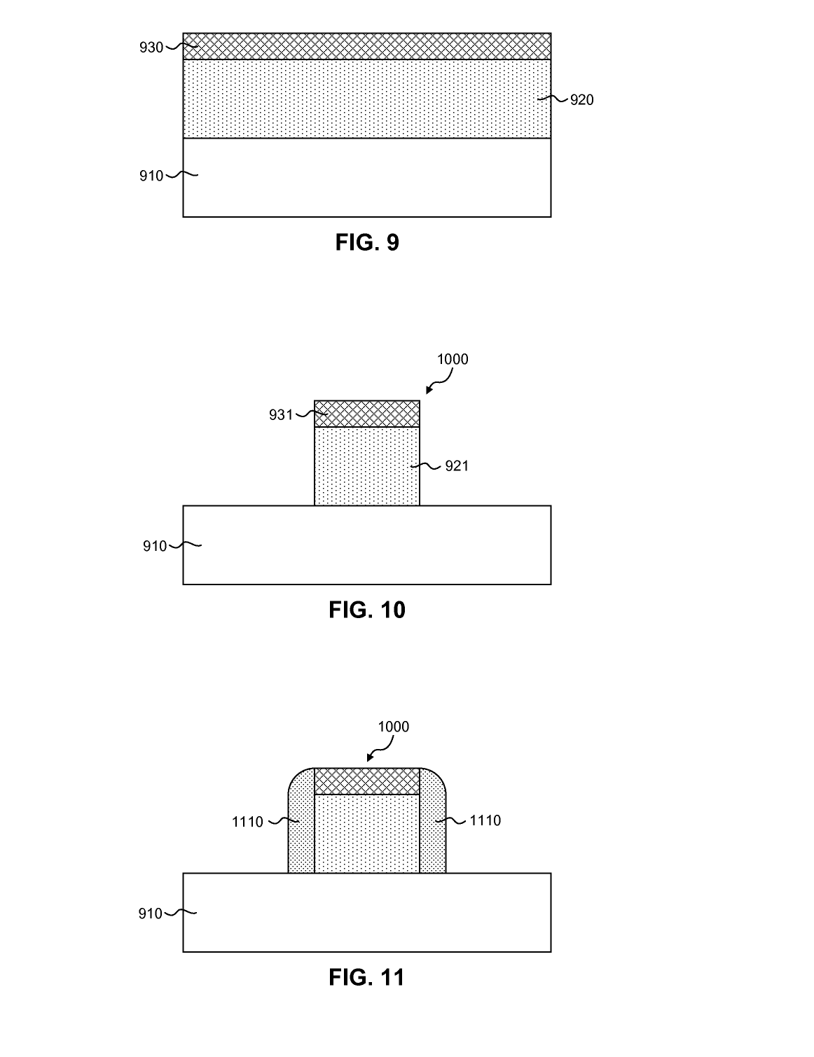

Referring to FIG. 10, gate 1000, which may include gate electrode 921 and hard mask 931 is formed on a top surface of semiconductor 910. Gate 1000 may be formed by etching gate stack 920 to form gate electrode 921 and etching hard mask layer 930 to form hard mask 931. Gate stack 920 and hard mask layer 930b may be etched using any etching process known in the art, including, for example, an anisotropic etching process such as RIE. Further, additional masking and photolithography steps may be used to define the dimensions of the gate prior to etching.

Referring to FIG. 11, sacrificial spacers 1110 are formed on the sidewalls of gate 1000. Sacrificial spacers 1110 may be formed, for example, by depositing a silicon nitride layer over gate 1000 and then removing excess material using an anisotropic reactive ion etching process, such as RIE (not shown). Due to the etching process, sacrificial spacers 410 may have a curved top surface on its edge opposite gate 1000. Sacrificial spacers 1110 may be made of materials including, but not limited to, silicon nitride, silicon oxide, silicon carbide and may be approximately 2 nm to approximately 100 nm thick, preferably approximately 2 nm to approximately 50 nm.

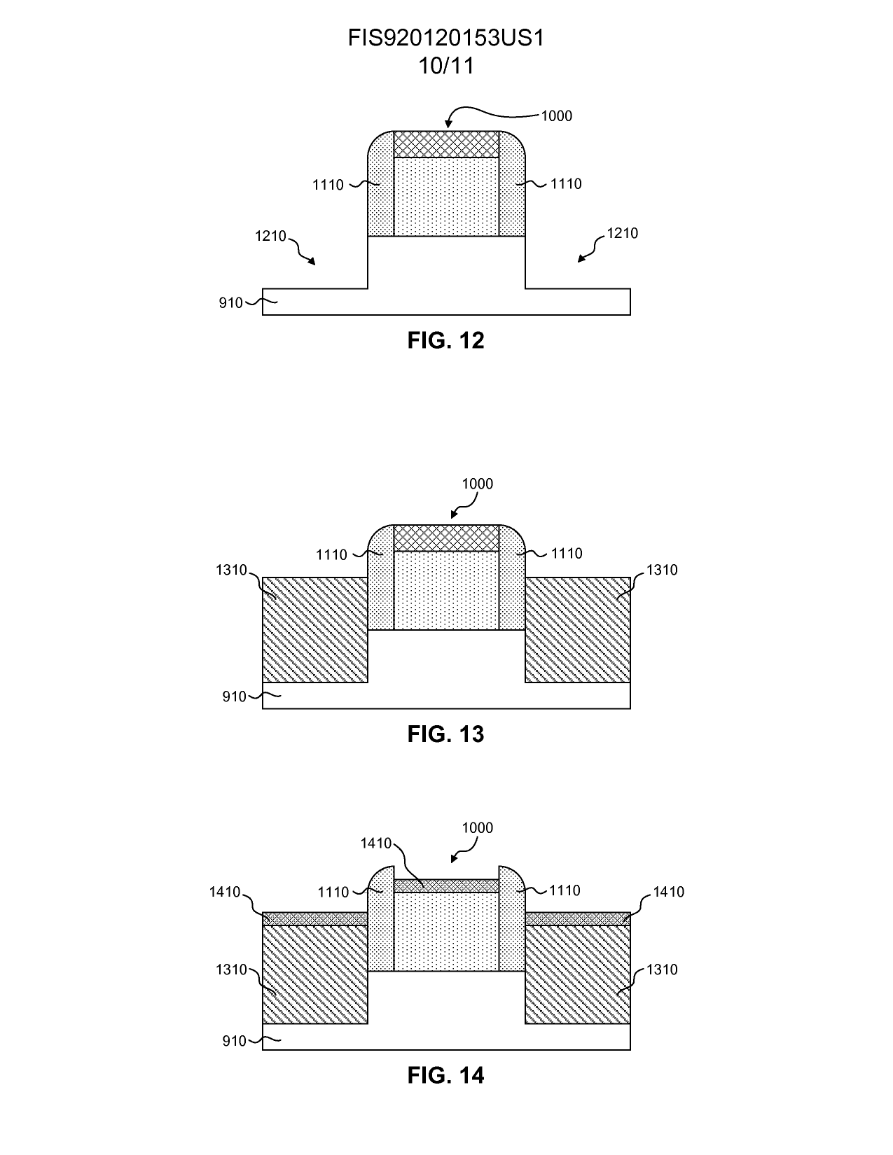

Referring to FIG. 12, source or drain recess regions 1210 may be formed in semiconductor substrate 910. Source or drain recess regions 1210 may be formed by etching semiconductor substrate 910 using, for example, RIE. Source or drain recess regions 1210 will be laterally separated from gate 1000 by sacrificial spacers 1110.

Referring to FIG. 13, source or drain regions 1310 may be formed in source or drain recess regions 1210. Source or drains 1310 are formed by, for example, epitaxially growing silicon-containing material in source or drain recess regions 1210 (FIG. 12). Depending on the nature of the semiconductor device being formed, this material may be, for example, silicon, silicon-germanium, or silicon carbide, and may be doped or undoped. In some embodiments, source or drain regions 1310 may extend vertically beyond the top surface of semiconductor substrate 910. In other embodiments, source or drain regions 1310 may be formed in the substrate 910 using, for example, ion implantation

Referring to FIG. 14, silicide layers 1410 are formed on a top surface of source or drain regions 1310 and gate electrode 921 of gate 1000. Before forming silicide layers 1410, hard mask 931 may be removed to expose gate electrode 921. Silicide layers 1410 may be formed by first depositing a uniform metal layer (not shown) over the top surface of the structure of FIGS. 13. The metal layer may be deposited by any thin film deposition technique available in the industry including, but not limited to, physical vapor deposition (i.e. sputter deposition) or chemical vapor deposition or evaporation. The metal layer may be made of materials including, for example, nickel, platinum, titanium, cobalt or some combination thereof, and may be approximately 3 to approximately 10 nm. The metal layer is then annealed (not shown) so that the metal layer reacts with any underlying reactive surfaces (primarily silicon-containing materials) to form silicide layers 1410. The annealing process may typically be performed by a rapid thermal annealing (RTA) process at peak temperatures ranging from approximately 300 to approximately 900 degrees Celsius, depending on the silicide material. After removal of any remaining unreacted metal material (not shown), silicide layers 1410 may remain directly in contact with source or drain regions 1310 and gate electrode 921, as shown in FIG. 14. In embodiments where gate electrode 921 is made of a metal such as copper, aluminum, or tungsten, silicide layer 1410 may not be present on the top surface of gate electrode 921.

Referring to FIG. 15, sacrificial spacers 1110 are removed from between source or drain regions 1310b and gate 1000 to form spacer recess regions 1510. Spacers 410 may be selectively etched so that they are removed without causing substantial damage to any other element of the structure. Sacrificial spacers 1100 may be removed by a suitable wet chemical etch process that selectively removes the spacer material. For example, silicon nitride spacer removal, may be accomplished by the use of hot phosphoric acid, hydrofluoric acid, or a combination thereof.

Referring to FIG. 16, spacer recess regions 1510 (FIG. 15) may be filled by oxide spacers 1610. Oxide spacers 1610 may be formed by may be formed by first depositing a silicon precursor such as trisilylamine [TSA, (SiH₃)₃N] via chemical vapor deposition with an oxygen (O₂) and ammonia (NH₃) mixture. The TSA may be deposited at temperatures below approximately 50° C. to enhance formation of short-chain polymers on the surface of the structure resulting in a liquid-like flowable film capable of filling dense, high- aspect ratio re-entrant profiles, such as spacer recess regions 1510. After the low temperature deposition of TSA, the wafer may be steam annealed between approximately 350 to approximately 550° C. for approximately 2 to approximately 4 hours to allow dehydrogenation and denitrogenation of TSA leading to formation of silicon oxide (SiO₂) capable of filling spacer recess regions 1510 without leaving a substantial volume of voids. In some embodiments, oxide spacers 1610 may extend beyond spacer recess regions 1510, and, for example, fully cover the top surface of the structure depicted in FIG. 15. In some embodiments, some or all excess oxide may be removed by, for example, CMP. After formation of oxide spacers 810, the structure is ready for standard back-end-of-the-line processes, including deposition of interlevel dielectric layers and contact formation.

While a method of forming both a finFET and planar FET are discussed above in conjunction with FIGS. 1A-6D and FIGS. 9-14, respectively, it is understood that there exists in the art many different methods of forming such structures and that embodiments of the present invention are not limited to the methods specifically disclosed. Rather, embodiments of the present invention may include steps of forming a finFET or planar FET having non-oxide sacrificial spacers using any known method, removing the sacrificial spacers without substantially damaging the surrounding structures, and replacing the sacrificial spacers with oxide spacers.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein. It is therefore intended that the present invention not be limited to the exact forms and details described and illustrated but fall within the scope of the appended claims.

1. A method of forming a field-effect transistor structure with oxide spacers, the method comprising:
forming a gate having a sidewall;
forming a sacrificial spacer on the sidewall of the gate;
forming a source or drain region, wherein the source or drain region is separated from the gate by the sacrificial spacer;
removing the sacrificial spacer to form a spacer recess region; and
forming an oxide spacer in the spacer recess region, wherein the oxide spacer covers an uppermost surface of the gate and provides oxygen to the transistor structure.

2. The method of claim 1, wherein forming the gate having the sidewall comprises:
forming a gate stack on a semiconductor substrate; and
etching the gate stack to form the gate.

3. The method of claim 1, wherein forming the gate having the sidewall comprises forming the gate over a semiconductor fin on an insulator layer.

4. The method of claim 1, wherein removing the sacrificial spacer to form the spacer recess region comprises using a wet chemical etch process capable of selectively removing nitride.

5. The method of claim 4, wherein the wet chemical etch process comprises at least one of hot phosphoric acid and hydrofluoric acid.

6. (canceled)

7. The method of claim 1, wherein forming an oxide spacer in the spacer recess region comprises:
depositing trisilylamine in the spacer recess region via a chemical vapor deposition process with an oxygen and ammonia mixture; and
steam-annealing the transistor structure.

8. The method of claim 7, wherein the trisilylamine is deposited at a temperature of below approximately 50° C.

9. The method of claim 7, wherein the transistor structure is steam-annealed at a temperature of between approximately 350° C. and approximately 550° C.

10. (canceled)

11. A field effect transistor structure comprising:
a gate having a sidewall;
a source or drain region; and
an oxide spacer on the sidewall of the gate; wherein the oxide spacer separates the gate from the source/drain region and provides oxygen to the gate.

12. The structure of claim 11, wherein the oxide spacer comprises silicon oxide.

13. The structure of claim 12, wherein the oxide spacer further covers a top portion of the source or drain region.

14. The structure of claim 12, wherein the gate comprises a gate electrode and a high-k dielectric layer on the semiconductor substrate.

15. The structure of claim 14, wherein the high-k dielectric layer comprises a hafnium-based material.

16. The structure of claim 11, wherein the field effect transistor structure comprises a planar field effect transistor.

17. The structure of claim 16, wherein the source or drain region comprises a raised source or drain.

18. The structure of claim 11, wherein the field effect transistor structure comprises a fin field effect transistor.
